(19) United States
(12) Patent Application Publication
(10) Pub. No.: US 2025/0081466 A1
(43) Pub. Date: Mar. 6, 2025

(54) SEMICONDUCTOR MEMORY DEVICE

(71) Applicant: SK hynix Inc., Icheon-si Gyeonggi-do (KR)

(72) Inventor: Sung Wook JUNG, Icheon-si Gyeonggi-do (KR)

(73) Assignee: SK hynix Inc., Icheon-si Gyeonggi-do (KR)

(21) Appl. No.: 18/433,949

(22) Filed: Feb. 6, 2024

(30) Foreign Application Priority Data
Aug. 30, 2023 (KR) 10-2023-0114326

(51) Int. Cl. H10B 43/40; G11C 16/08; H10B 43/27

(52) U.S. Cl. CPC H10B 43/40; H10B 43/27; G11C 16/08

(57) ABSTRACT

Provided herein are a semiconductor memory device and a method of manufacturing the semiconductor memory device. The semiconductor memory device includes a transistor, a cell array structure, a molded insulating structure including a first area disposed between the transistor and the cell array structure and overlapping with the transistor and a second area extending sideways from the first area, a pass gate disposed in the second area of the molded insulating structure, an active pillar penetrating the pass gate, and a pass gate insulating layer disposed between the active pillar and the pass gate.

### CROSS-REFERENCE TO RELATED APPLICATION

The present application claims priority under 35 U.S.C. § 119 (a) to Korean patent application number 10-2023-0114326 filed on Aug. 30, 2023, in the Korean Intellectual Property Office, the entire disclosure of which is incorporated by reference herein.

### BACKGROUND

### 1. Technical Field

Various embodiments of the present disclosure relate to a semiconductor memory device and a method of manufacturing the semiconductor memory device, and more particularly to a three-dimensional (3D) semiconductor memory device and a method of manufacturing the 3D semiconductor memory device.

### 2. Related Art

A semiconductor memory device is applied not only to small-sized electronic devices but also to electronic devices in various fields, such as vehicles, medical appliances, and data centers. Accordingly, there is an increasing demand for semiconductor memory devices.

The semiconductor memory device may include memory cells for storing data. In order to achieve high capacity in the semiconductor memory device, the development of technology for a 3D semiconductor memory device including memory cells arranged in three dimensions is being actively conducted.

### SUMMARY

According to an embodiment of the present disclosure, a semiconductor memory device may include a transistor, a molded insulating structure including a first area overlapping with the transistor and a second area extending sideways from the first area, a pass gate disposed in the second area of the molded insulating structure, an active pillar penetrating the pass gate, a pass gate insulating layer disposed between the active pillar and the pass gate, a first conductive connection structure disposed in the first area of the molded insulating structure and coupled to the transistor, and a cell array structure including a plurality of memory cells arranged over the molded insulating structure in three dimensions.

According to an embodiment of the present disclosure, a semiconductor memory device may include a semiconductor substrate including a first surface facing a first direction and a second surface facing a direction opposite to the first direction, a gate stacked body including a plurality of conductive layers stacked over the first surface of the semiconductor substrate in the first direction, a molded insulating structure disposed between the gate stacked body and the semiconductor substrate and including a first area and a second area extending sideways from the first area, a first conductive connection structure disposed in the first area of the molded insulating structure and extending to contact the semiconductor substrate, a pass gate disposed in the second area of the molded insulating structure, an active pillar penetrating the pass gate, and a pass gate insulating layer disposed between the active pillar and the pass gate.

According to an embodiment of the present disclosure, a method of manufacturing a semiconductor memory device may include forming a first insulating layer including a first area covering a transistor and a second area extending sideways from the first area, forming a second insulating layer over the first insulating layer, etching the first insulating layer and the second insulating layer so that a contact hole and an active hole are formed, wherein the contact hole passes through the first insulating layer and a portion of the second insulating layer overlapping with the first area of the first insulating layer and wherein the active hole passes through the first insulating layer and a portion of the second insulating layer overlapping with the second area of the first insulating layer, forming a pass gate insulating layer and an active pillar in the active hole, forming a first conductive connection structure in the contact hole, forming a third insulating layer over the second insulating layer to cover the first conductive connection structure and the active pillar, forming a slit passing through the second insulating layer and the third insulating layer, and replacing a portion of the second insulating layer with a pass gate through the slit.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell array and a pass circuit according to an embodiment of the present disclosure.

FIGS. 3 and 4 are sectional views illustrating semiconductor memory devices according to embodiments of the present disclosure.

FIG. 5A is a sectional view illustrating a pass transistor group according to an embodiment of the present disclosure, and FIG. 5B is a plan view illustrating the pass transistor group taken along line A-A′ of FIG. 5A.

FIGS. 6A to 6K are sectional views illustrating a method of manufacturing first conductive connection structures and a pass transistor group of a semiconductor memory device according to an embodiment of the present disclosure.

FIG. 7 is a block diagram illustrating an electronic system including a semiconductor memory device according to an embodiment of the present disclosure.

### DETAILED DESCRIPTION

Specific structural or functional descriptions of embodiments according to the concept of the present disclosure, disclosed in the present specification or application, are exemplified to explain the embodiments according to the concept of the present disclosure. The embodiments according to the concept of the present disclosure should not be construed as being limited to embodiments described in the present specification or application and may be modified in various forms and replaced with other equivalent embodiments.

It will be understood that, although the terms “first,” “second,” etc. may be used herein to describe various elements, these elements should not be limited by these terms. These terms are only used to distinguish one element from another element, and the order or number of components is not limited by the terms. In addition, it is not construed as limiting the number of components unless there is a special limitation on components expressed in singular or plural numbers.

Various embodiments of the present disclosure are directed to a semiconductor memory device having an improved degree of integration and a method of manufacturing the semiconductor memory device.

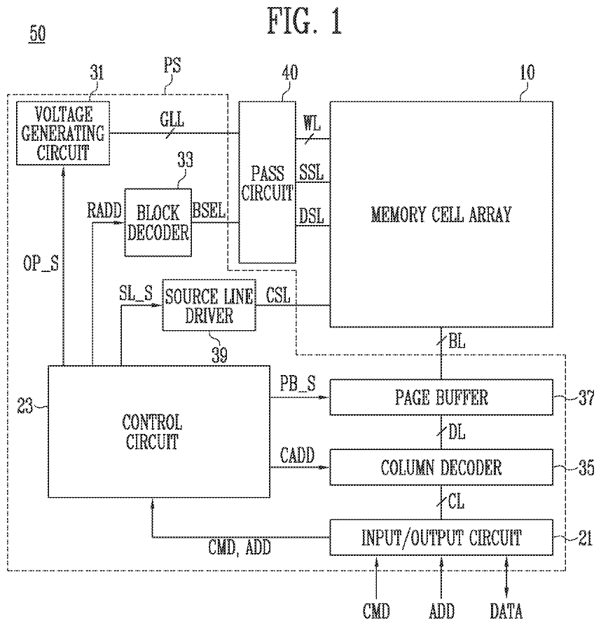

FIG. 1 is a block diagram illustrating a semiconductor memory device according to an embodiment of the present disclosure.

Referring to FIG. 1, a semiconductor memory device 50 may include a memory cell array 10, a pass circuit 40, and a peripheral circuit structure PS.

The memory cell array 10 may include a plurality of memory blocks. Each memory block may include a plurality of memory cells. Each memory cell may be a nonvolatile memory cell. In an embodiment, each memory cell may be a NAND flash memory cell. Hereinafter, embodiments of the present disclosure will be described based on the semiconductor memory device 50 including NAND flash memory cells, but embodiments of the present disclosure are not limited thereto. For example, each memory cell may be implemented as a ferroelectric memory cell, a variable-resistance memory cell, or the like.

The pass circuit 40 may be coupled to the memory cell array 10 through a plurality of local lines. In an embodiment, the plurality of local lines may include a plurality of word lines WL, at least one source select line SSL, and at least one drain select line DSL.

The peripheral circuit structure PS may perform a program operation that stores data in the memory cell array 10, a read operation that outputs data stored in the memory cell array 10, and an erase operation that erases data stored in the memory cell array 10. In an embodiment, the peripheral circuit structure PS may include an input/output circuit 21, a control circuit 23, a voltage generating circuit 31, a block decoder 33, a column decoder 35, a page buffer 37, and a source line driver 39.

The input/output circuit 21 may transfer a command CMD and an address ADD, received from a device (e.g., a memory controller) external to the semiconductor memory device 50, to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate and output various operating voltages that are used for a program operation, a read operation, and an erase operation in response to the operation signal OP_S. The operating voltages output from the voltage generating circuit 31 may be transmitted to the pass circuit 40 through a plurality of global lines GLL.

The block decoder 33 may output a block selection signal in response to the row address RADD. The block selection signal output from the block decoder 33 may be transmitted to the pass circuit 40 through a block select line BSEL.

The pass circuit 40 may transfer the operating voltages, received through the plurality of global lines GLL, to the drain select line DSL, the word lines WL, and the source select line SSL in response to the block selection signal received through the block select line BSEL.

The column decoder 35 may transmit the data DATA, input from the input/output circuit 21, to the page buffer 37 or transmit data DATA, stored in the page buffer 37, to the input/output circuit 21 in response to the column address CADD. The column decoder 35 may exchange data DATA with the input/output circuit 21 through column lines CL. The column decoder 35 may exchange data DATA with the page buffer 37 through data lines DL.

The page buffer 37 may store the read data, received through bit lines BL, in response to the page buffer control signal PB_S. The page buffer 37 may sense the voltages or currents of the bit lines BL during a read operation. The page buffer 37 may be coupled to the memory cell array 10 through the bit lines BL.

The source line driver 39 may control a voltage applied to a common source line CSL in response to the source line control signal SL_S. The source line driver 39 may be coupled to the memory cell array 10 through the common source line CSL.

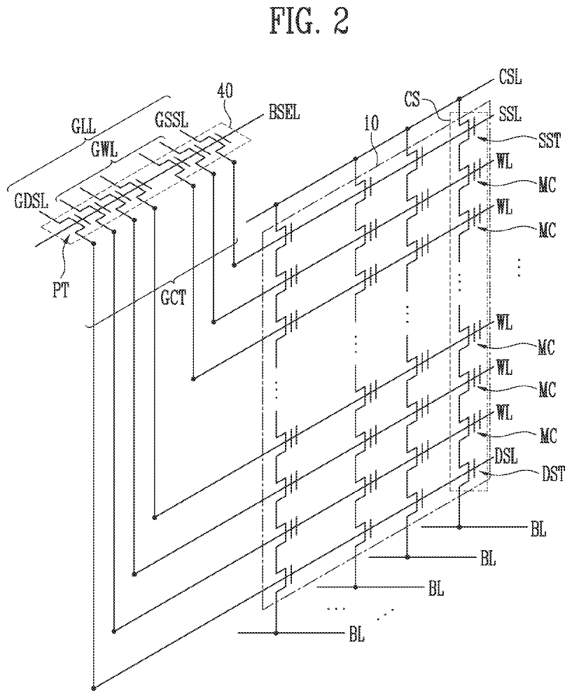

FIG. 2 is a circuit diagram illustrating a memory cell array and a pass circuit according to an embodiment of the present disclosure.

Referring to FIG. 2, the memory cell array 10 may include a plurality of memory cell strings CS. The plurality of memory cell strings CS may be coupled to a plurality of bit lines BL and a common source line CSL.

Each memory cell string CS may include at least one source select transistor SST, a plurality of memory cells MC, and at least one drain select transistor DST.

The source select transistor SST may control an electrical connection between the plurality of memory cells MC and the common source line CSL. The drain select transistor DST may control an electrical connection between the plurality of memory cells MC and the corresponding bit line BL.

One source select transistor SST or two source select transistors connected in series may be disposed between the common source line CSL and the plurality of memory cells MC. One drain select transistor DST or two or more drain select transistors connected in series may be disposed between each bit line BL and a plurality of memory cells MC of a memory cell string CS corresponding to the bit line BL.

A plurality of gates of the plurality of memory cells MC may be coupled to the plurality of word lines WL, respectively. A gate of the source select transistor SST may be coupled to a source select line SSL. A gate of the drain select transistor DST may be coupled to the drain select line DSL.

The source select line SSL, the drain select line DSL, and the plurality of word lines WL may be coupled to the pass circuit 40. The pass circuit 40 may include pass transistor groups, each including a plurality of pass transistors PT coupled to the same pass block select line BSEL. The plurality of pass transistors PT may be coupled to a plurality of gate contact plugs GCT, respectively. The plurality of gate contact plugs GCT may be coupled to the source select line SSL, the drain select line DSL, and the plurality of word lines WL, respectively. Each of the pass transistors PT may be coupled to a corresponding local line among the source select line SSL, the drain select line DSL, and the plurality of word lines WL via the gate contact plug GCT corresponding to the pass transistor PT.

In response to the block selection signal applied to the block select line BSEL, the plurality of pass transistors PT may transfer the voltages that are applied to the plurality of global lines GLL to the source select line SSL, the drain select line DSL, and the plurality of word lines WL. The plurality of global lines GLL may include a global source select line GSSL, a global drain select line GDSL, and a plurality of global word lines GWL, which correspond to the source select line SSL, the drain select line DSL, and the plurality of word lines WL, respectively.

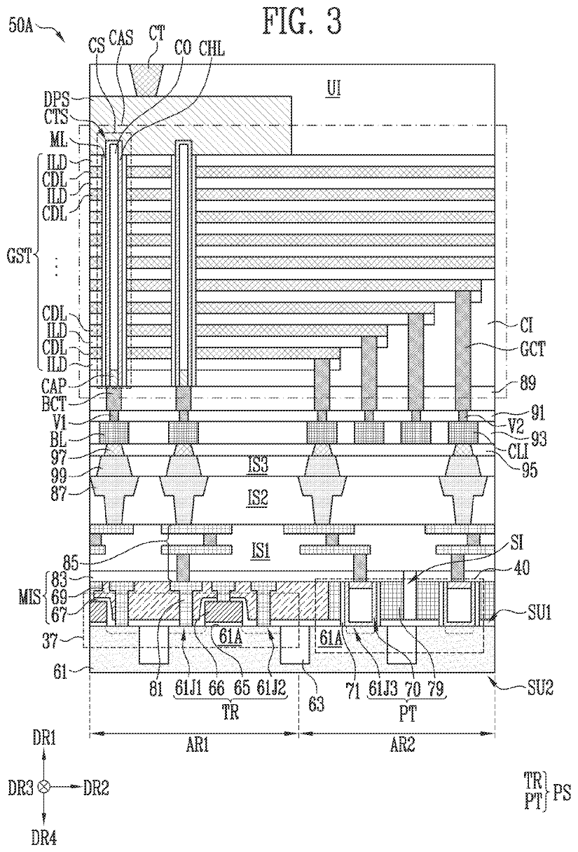

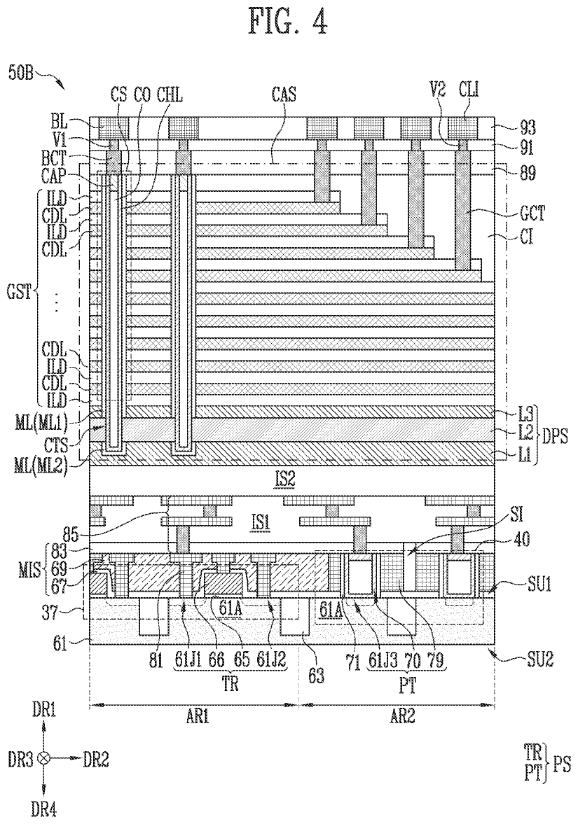

FIGS. 3 and 4 are sectional views illustrating semiconductor memory devices according to embodiments of the present disclosure.

Referring to FIGS. 3 and 4, a semiconductor memory device 50A and 50B may include a cell array structure CAS, a doped semiconductor structure DPS, a transistor TR, and a pass transistor PT of a peripheral circuit structure PS, and an interconnection structure for an electrical connection between the peripheral circuit structure PS and the cell array structure CAS.

The cell array structure CAS may include a plurality of memory cells arranged in three dimensions. In an embodiment, the plurality of memory cells may be included in the plurality of memory cell strings CS, described above with reference to FIG. 2. Each memory cell string CS may be coupled to a plurality of conductive layers CDL included in a gate stacked body GST. The plurality of conductive layers CDL may serve as at least one drain select line DSL, the plurality of word lines WL, and at least one source select line SSL, as illustrated in FIG. 2. Each of the memory cells may be coupled to the conductive layer that serves as a word line among the plurality of conductive layers CDL.

The gate stacked body GST may be disposed over a semiconductor substrate 61. The semiconductor substrate 61 may include a first surface SU1 facing a first direction DR1. The gate stacked body GST may further include a plurality of interlayer insulating layers ILD and the plurality of conductive layers CDL that are alternately stacked in the first direction DR1. Each conductive layer CDL and each interlayer insulating layer ILD may extend in a plane created by a second direction DR2 and a third direction DR3, the plane being parallel to the first surface SU1 and perpendicular to the first direction DR1. The above-described first direction DR1, second direction DR2, and third direction DR3 may respectively correspond to an X axis, a Y axis, and a Z axis. Hereinafter, a direction in which a second surface SU2 of the semiconductor substrate 61 faces may be defined as a fourth direction DR4, which is the opposite direction of the first direction DR1, and the second surface SU2 may be defined as a surface on the opposite side of the first surface SU1.

Each of the plurality of conductive layers CDL may include at least one of a doped semiconductor layer and a metal layer. The doped semiconductor layer of each conductive layer CDL may include a doped silicon layer. The metal layer of each conductive layer CDL may include tungsten, copper, molybdenum, or the like. The plurality of conductive layers CDL may further include a metal nitride layer. The metal nitride layer may include a titanium nitride, a tantalum nitride, etc. Each of the plurality of interlayer insulating layers ILD may include a silicon oxide layer or the like.

The channel region of each memory cell string CS may be defined by a channel layer CHL, and a data storage area of each memory cell string CS may be defined by a memory layer ML. The memory layer ML and the channel layer CHL may penetrate the gate stacked body GST. The memory layer ML and the channel layer CHL may be disposed in a channel hole of the gate stacked body GST. The channel hole may extend in the first direction DR1 to pass through the plurality of conductive layers CDL and the plurality of interlayer insulating layers ILD. The channel layer CHL may be formed of a semiconductor material. In an embodiment, the channel layer CHL may include silicon, germanium, or a mixture thereof.

The channel layer CHL may include a contact surface CTS contacting the doped semiconductor structure DPS. The doped semiconductor structure DPS may be used as at least one of a source region and a well region. In an embodiment, the doped semiconductor structure DPS may be provided as a source region including an n-type impurity as a majority carrier. However, embodiments of the present disclosure are not limited thereto. In an embodiment, the doped semiconductor structure DPS may include at least one of a first conductive doped region including an n-type impurity as a majority carrier and a second conductive doped region including a p-type impurity as a majority carrier. The first conductive doped region may be provided as a source region, and the second conductive doped region may be provided as a well region.

The doped semiconductor structure DPS and the gate stacked body GST may be disposed to be spaced apart from the semiconductor substrate 61 in the first direction DR1. The locations of the doped semiconductor structure DPS and the gate stacked body GST may be designed in various manners. In an embodiment, as illustrated in FIG. 3, the doped semiconductor structure DPS may be disposed to be farther away from the semiconductor substrate 61 than the gate stacked body GST is from the semiconductor substrate 61 in the first direction DR1. In another embodiment, as illustrated in FIG. 4, the doped semiconductor structure DPS may be disposed to be closer to the semiconductor substrate 61 compared to the distance between the gate stacked body GST and the semiconductor substrate 61 in the first direction DR1.

Referring to FIG. 3, the gate stacked body GST may be disposed between the doped semiconductor structure DPS and the semiconductor substrate 61. The contact surface CTS of the channel layer CHL may be coplanar with surfaces of the doped semiconductor structure DPS. In an embodiment, the doped semiconductor structure DPS may include a groove in which the channel layer CHL can be inserted, and the contact surface CTS of the channel layer CHL may be coplanar with the surface of the groove defined in the doped semiconductor structure DPS.

The gate stacked body GST and the doped semiconductor structure DPS may be covered with an upper insulating layer UI. A conductive contact CT coupled to the doped semiconductor structure DPS may be disposed in the upper insulating layer UI. Although not illustrated in the drawing, the conductive contact CT may transmit an electrical signal from the common source line disposed over the upper insulating layer UI to the doped semiconductor structure DPS.

Referring to FIG. 4, the doped semiconductor structure DPS may be disposed between the gate stacked body GST and the semiconductor substrate 61. The contact surface CTS of the channel layer CHL may be coplanar with the surfaces of the doped semiconductor structure DPS. In an embodiment, the doped semiconductor structure DPS may include a first semiconductor layer L1, a second semiconductor layer L2, and a third semiconductor layer L3 that are stacked in the first direction DR1. The channel layer CHL may penetrate the third semiconductor layer L3 and may extend into the first semiconductor layer L1. The second semiconductor layer L2 may include a sidewall coplanar with the contact surface CTS of the channel layer CHL. In other words, the sidewall of the second semiconductor layer L2 may contact the channel layer CHL.

Each of the first semiconductor layer L1, the semiconductor layer L2, and the third semiconductor layer L3 may include at least one of an n-type impurity and a p-type impurity. In an embodiment, each of the first semiconductor layer L1, the semiconductor layer L2, and the third semiconductor layer L3 may be provided as a first conductive doped region including an n-type impurity as a majority carrier. In another embodiment, each of the second semiconductor layer L2 and the third semiconductor layer L3 may be provided as the first conductive doped region including an n-type impurity as a majority carrier, and the first semiconductor layer L1 may be provided as a second conductive doped region including a p-type impurity as a majority carrier. The first conductive doped region may be provided as a source region, and the second conductive doped region may be provided as a well region. Each of the first semiconductor layer L1, the second semiconductor layer L2, and the third semiconductor layer L3 may include a semiconductor material, such as silicon. However, the embodiments of the present disclosure are not limited thereto, and the doped regions of the first semiconductor layer L1, the second semiconductor layer L2, and the third semiconductor layer L3 may be designed in various manners.

The memory layer ML may be interposed between each of the first semiconductor layer L1 and the third semiconductor layer L3 and the channel layer CHL. The memory layer ML may be separated into a first memory layer ML1 and a second memory layer ML2 through a contact between the second semiconductor layer L2 and the channel layer CHL. The first memory layer ML1 may be interposed between the third semiconductor layer L3 and the channel layer CHL and may extend in the first direction DR1 to be interposed between the gate stacked body GST and the channel layer CHL. The second memory layer ML2 may be interposed between the channel layer CHL and the first semiconductor layer L1.

Referring to FIGS. 3 and 4, a core insulating layer CO and a capping pattern CAP may be disposed in a central region of the channel hole passing through the gate stacked body GST. The channel layer CHL may extend along the side of the core insulating layer CO and the side of the capping pattern CAP. The capping pattern CAP may serve as a drain junction of the memory cell string CS. The capping pattern CAP may include at least one of an n-type impurity and a p-type impurity. In an embodiment, the capping pattern CAP may include an n-type impurity as a majority carrier.

Each of the memory layer ML, illustrated in FIG. 3, and the first memory layer ML1, illustrated in FIG. 4, may include a blocking insulating layer between the channel layer CHL and the gate stacked body GST, a data storage layer between the blocking insulating layer and the channel layer CHL, and a tunnel insulating layer between the data storage layer and the channel layer CHL. The blocking insulating layer may include an insulating material capable of blocking charges. The tunnel insulating layer may include an insulating material that enables charge tunneling. The blocking insulating layer may include an insulating layer having a dielectric constant that is higher than that of the tunnel insulating layer. The data storage layer may be formed of a material layer capable of storing data changed through Fowler-Nordheim tunneling. In an embodiment, the data storage layer may be formed of a charge trap insulating layer or an insulating layer containing conductive nanodots. The charge trap insulating layer may include a silicon nitride layer. However, the embodiments of the present disclosure are not limited thereto, and the data storage layer may be formed of a material layer that is capable of storing information based on an operating principle other than Fowler-Nordheim tunneling. In an embodiment, the data storage layer may include a phase-change material layer, a ferroelectric layer, etc. In this case, each of the channel layer CHL, the core insulating layer CO, and the capping pattern CAP may be replaced with a pillar-shaped electrode structure.

The second memory layer ML2, illustrated in FIG. 4, may be configured in the same manner as the first memory layer ML1.

Referring to FIGS. 3 and 4, the semiconductor memory device 50A and 50B may further include bit lines BL. The bit lines BL may be disposed to be spaced apart from the semiconductor substrate 61 in the first direction DR1. The locations of the bit lines BL may be designed in various manners. In an embodiment, as illustrated in FIG. 3, the bit lines BL may be disposed to be closer to the semiconductor substrate 61 compared to the distance between the gate stacked body GST and the semiconductor substrate 61 in the first direction DR1. In other words, the bit lines BL may be disposed between the gate stacked body GST and the semiconductor substrate 61. In an embodiment, as illustrated in FIG. 4, the bit lines BL may be disposed to be farther away from the semiconductor substrate 61 than the gate stacked body GST is from the semiconductor substrate 61 in the first direction DR1. In other words, the gate stacked body GST may be disposed between the bit lines BL and the semiconductor substrate 61.

Referring to FIGS. 3 and 4, each bit line BL may be coupled to the capping pattern CAP via a bit line connection structure disposed between the gate stacked body GST and the bit line BL. In an embodiment, the bit line connection structure may include a conductive bit contact plug BCT and a first conductive via structure V1. The conductive bit contact plug BCT may be disposed in a first interlayer insulating structure 89 between the gate stacked body GST and the bit line BL and may be coupled to the capping pattern CAP. The first conductive via structure V1 may be disposed in a second interlayer insulating structure 91 between the first interlayer insulating structure 89 and the bit line BL and may electrically connect the conductive bit contact plug BCT to the bit line BL. The bit line BL may be disposed in a bit line level insulating layer 93. The bit line level insulating layer 93 may overlap with the first interlayer insulating structure 89 with the second interlayer insulating structure 91 interposed therebetween.

The connection between the bit line BL and the capping pattern CAP is not limited to the above embodiments. Although not illustrated in the drawings, the bit line BL may be directly coupled to the capping pattern CAP.

A covering insulating structure CI may be formed between the gate stacked body GST and the first interlayer insulating layer 89. The channel layer CHL and the capping pattern CAP may extend towards the bit line BL to penetrate a portion of the covering insulating structure CI.

In an embodiment, the plurality of conductive layers CDL of the gate stacked body GST may include end portions forming a stepped structure. Here, the covering insulating structure CI may cover the stepped structure. Embodiments of the present disclosure are not limited thereto, and the plurality of conductive layers CDL of the gate stacked body GST may have substantially the same length in a second direction DR2, without forming the stepped structure.

Referring to FIGS. 3 and 4, the semiconductor substrate 61 may include a plurality of active regions 61A partitioned by an isolation layer 63. Each active region 61A may include a first junction region 61J1 and a second junction region 61J2 that are provided as the source junction and the drain junction of the transistor TR, respectively, or may include a third junction region 61J3 that is provided as the source junction of the pass transistor PT. Each of the first junction region 61J1, the second junction region 61J2, and the third junction region 61J3 may include at least one of an n-type impurity and a p-type impurity. In an embodiment, when each of the transistor TR and the pass transistor PT is provided as an N-channel metal oxide semiconductor (NMOS) transistor, each of the first junction region 61J1, the second junction region 61J2, and the third junction region 61J3 may include an n-type impurity as a majority carrier.

The transistor TR may be included in a circuit other than the pass circuit 40 of the peripheral circuit structure PS and may be distinguished from the pass transistor PT forming the pass transistor group. In an embodiment, the transistor TR may be included in a page buffer 37.

A gate insulating layer 65 and a gate electrode 66 of the transistor TR may be stacked on the semiconductor substrate 61 within the active region 61A of the semiconductor substrate 61 disposed between the first junction region 61J1 and the second junction region 61J2.

A molded insulating structure MIS may be disposed between the semiconductor substrate 61 and the gate stacked body GST. The molded insulating structure MIS may include a first area AR1 overlapping with the transistor TR and a second area AR2 extending sideways (e.g., in the second direction DR2) from the first area AR1.

A plurality of first conductive connection structures 81 may be disposed in the first area AR1 of the molded insulating structure MIS. The plurality of first conductive connection structures 81 may be included in an interconnection structure.

A pass gate 79 provided as the gate electrode of the pass transistor PT may be disposed in the second area AR2 of the molded insulating structure MIS. The pass gate 79 may be penetrated by an active pillar 70. A pass gate insulating layer 71 may be disposed between the active pillar 70 and the pass gate 79.

The molded insulating structure MIS may include a first insulating layer 67, a second insulating layer 69, and a third insulating layer 83. The first insulating layer 67 may be disposed over the semiconductor substrate 61 to cover the transistor TR. The first insulating layer 67 may extend along the lower surface of the pass gate 79. The second insulating layer 69 may be disposed over the first insulating layer 67. The second insulating layer 69 may face the side surface of the pass gate 79. The third insulating layer 83 may be disposed over the second insulating layer 69. The third insulating layer 83 may extend along the upper surface of the pass gate 79.

The plurality of first conductive connection structures 81 may include a first type-first conductive connection structure coupled to the gate electrode 66 of the transistor TR, a second type-first conductive connection structure coupled to the first junction region 61J1 of the transistor TR, and a third type-first conductive connection structure coupled to the second junction region 61J2 of the transistor TR. The plurality of first conductive connection structures 81 may penetrate at least one of the first insulating layer 67, the second insulating layer 69, and the third insulating layer 83 in the first area AR1 of the molded insulating structure MIS. In an embodiment, each of the first conductive connection structures 81 may contact a corresponding gate electrode 66, first junction region 61J1, or second junction region 61J2 of the transistor TR and may extend towards the cell array structure CAS to penetrate the first insulating layer 67 and the second insulating layer 69.

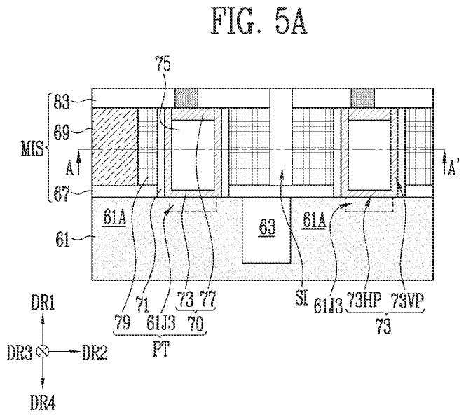

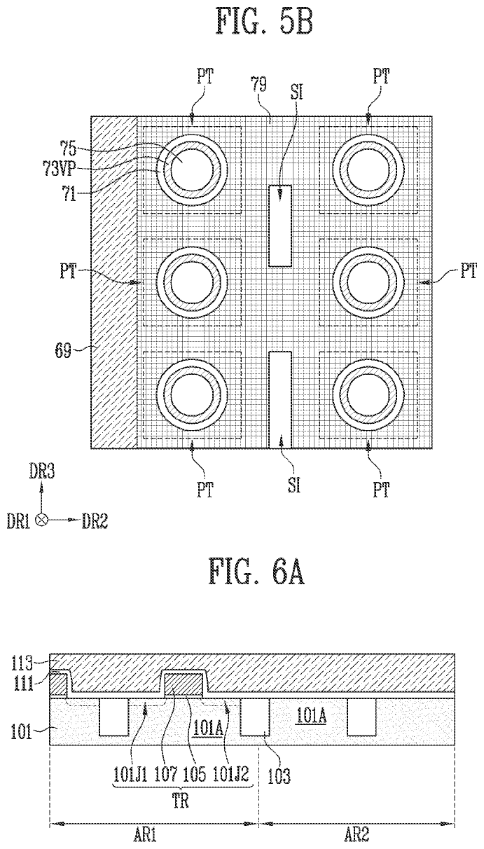

FIG. 5A is a sectional view illustrating a pass transistor group according to an embodiment of the present disclosure, and FIG. 5B is a plan view illustrating the pass transistor group taken along line A-A′ of FIG. 5A.

Referring to FIGS. 5A and 5B, the pass transistor group may include a plurality of pass transistors PT respectively corresponding to the plurality of conductive layers CDL illustrated in FIG. 3 or 4. The plurality of pass transistors PT in the pass transistor group may be coupled to the same pass gate 79.

The channel of each pass transistor PT of the pass transistor group may be defined by an active pillar 70. The active pillar 70 may be surrounded by the pass gate 79. According to this structure, each pass transistor PT may be formed in a surrounding gate transistor (SGT) structure. As the pass transistor PT is formed in the SGT structure, an area occupied by the pass transistor PT may be reduced, and on/off characteristics of the pass transistor PT may be improved.

The pass gate 79 may be formed of a conductive material. The pass gate 79 may be spaced apart from the semiconductor substrate 61 due to the first insulating layer 67 of a molded insulating structure MIS. The pass gate 79 may be formed using a process that replaces a portion of the second insulating layer 69 of the molded insulating structure MIS with a conductive material. In order to replace the portion of the second insulating layer 69 with the conductive material, a plurality of slits SI may be formed during a process of manufacturing the semiconductor memory device. The plurality of slits SI may remain in the pass gate 79 while being spaced apart from each other. Each of the slits SI may be filled with an insulating material or a conductive material.

In order to use the process that replaces the portion of the second insulating layer 69 with the conductive material, the second insulating material 69 may include a material having an etch selectivity with respect to the first insulating layer 67 and the third insulating layer 83. In an embodiment, each of the first insulating layer 67 and the third insulating layer 83 may include a silicon oxide layer, and the second insulating layer 69 may include a silicon nitride layer.

The active pillar 70 may penetrate the first insulating layer 67 to contact the semiconductor substrate 61. The active pillar 70 may include a channel layer 73 and a semiconductor capping pattern 77. The channel layer 73 and the semiconductor capping pattern 77 may include a semiconductor material, such as silicon or germanium.

The channel layer 73 may penetrate the first insulating layer 67 to contact the active region 61A of the semiconductor substrate 61. The channel layer 73 may include a horizontal portion 73HP and a vertical portion 73VP. The horizontal portion 73HP may contact a third junction region 61J3 formed in the active region 61A of the semiconductor substrate 61. The vertical portion 73VP may extend from the horizontal portion 73HP in a first direction DR1. The vertical portion 73VP may function as the channel of the pass transistor PT. The vertical portion 73VP may be an undoped region or a doped region including at least one of a p-type impurity and an n-type impurity. In an embodiment, the horizontal portion 73HP may be an undoped region or a doped region in the same manner as the vertical portion 73VP. In an embodiment, the horizontal portion 73HP may be a doped region that is doped with the same conductive impurity as the third junction region 61J3.

The vertical portion 73VP of the channel layer 73 may be formed in a tubular shape. The semiconductor capping pattern 77 may be disposed in a central region of the tubular shape provided by the vertical portion 73VP. The semiconductor capping pattern 77 may be disposed in an upper portion of the central region of the tubular shape, and a core insulating layer 75 may be disposed in a portion of the central region of the tubular shape below the semiconductor capping pattern 77. The semiconductor capping pattern 77 may be provided as the drain junction of the pass transistor PT. The semiconductor capping pattern 77 may include the same conductive impurity as the third junction region 61J3.

The channel length of the pass transistor PT may be proportional to the length of the vertical portion 73VP of the channel layer 73 in the first direction DR1. The length of the vertical portion 73VP may be proportional to the thickness of the second insulating layer 69 in the first direction DR1. The channel length of the pass transistor PT may be designed to transmit a higher operating voltage. The channel length of the pass transistor PT may be increased by controlling the thickness of the second insulating layer 69 in the first direction DR1. That is, because the channel length of the pass transistor PT may be increased even though the planar area of the semiconductor substrate 61 is not increased, the planar area of the semiconductor substrate 61 allocated by the pass transistor PT may be reduced. In order to secure the channel length of the pass transistor PT, the second insulating layer 69 may be formed to be thicker in the first direction DR1 compared to each of the first insulating layer 67 and the third insulating layer 83.

The pass gate insulating layer 71 may enclose the sidewall of the vertical portion 73VP of the channel layer 73.

Referring to FIGS. 3 and 4, the interconnection structure of the memory device 50A or 50B may further include a plurality of second conductive connection structures 85, a plurality of gate contact plugs GCT, a plurality of second conductive via structures V2, and a plurality of conductive lines CLI.

The plurality of second conductive connection structures 85 may be disposed in a first interposed insulating structure IS1. The first interposed insulating structure IS1 may be disposed between the gate stacked body GST and the molded insulating structure MIS. The plurality of second conductive connection structures 85 may include a first type-second conductive connection structure connected to the first conductive connection structures 81 and a second type-second conductive connection structure connected to the active pillar 70. Each of the second conductive connection structures 85 may include a vertical via pattern and a line pattern. The plurality of second conductive connection structures 85 may penetrate the third insulating layer 83 to contact the first conductive connection structures 81 or the semiconductor capping pattern (e.g. 77 of FIG. 5A) of the active pillar 70.

The plurality of gate contact plugs GCT may be respectively coupled to the plurality of conductive layers CDL of the gate stacked body GST. The plurality of gate contact plugs GCT may extend into the covering insulating structure CI. The plurality of gate contact plugs GCT may extend to penetrate the first interlayer insulating structure 89.

The plurality of second conductive via structures V2 may be disposed in a second interlayer insulating structure 91. The plurality of second conductive via structures V2 may be coupled to the plurality of gate contact plugs GCT, respectively.

The plurality of conductive lines CLI may be disposed in a bit line level insulating layer 93. The respective conductive lines CLI may be coupled to pass transistors PT corresponding thereto via conductive patterns having various structures.

In an embodiment, each conductive line CLI may be coupled to the corresponding pass transistor PT via a corresponding first conductive bonding structure 87, illustrated in FIG. 3, and a corresponding second conductive bonding structure 99, illustrated in FIG. 3.

Referring to FIG. 3, the plurality of first conductive bonding structures 87 may be disposed in a second interposed insulating structure IS2. The second interposed insulating structure IS2 may be disposed between the first interposed insulating structure IS1 and the gate stacked body GST. The plurality of first conductive bonding structures 87 may include metal, such as copper. The plurality of first conductive bonding structures 87 may be coupled to the plurality of second conductive connection structures 85, respectively. The plurality of first conductive bonding structures 87 may be bonded to the plurality of second conductive bonding structures 99.

The plurality of second conductive bonding structures 99 may be disposed in a third interposed insulating structure IS3. The third interposed insulating structure IS3 may be disposed between the second interposed insulating structure IS2 and the gate stacked body GST. The plurality of second conductive bonding structures 99 may include metal, such as copper.

The interconnection structure of the semiconductor memory device 50A may further include a plurality of third conductive via structures 97. The plurality of third conductive via structures 97 may be disposed in a fourth interlayer insulating structure 95. The plurality of third conductive via structures 97 may be coupled to the plurality of second conductive bonding structures 99, respectively. The plurality of third conductive via structures 97 may include a first type-third conductive via structure coupled to the bit line BL and a second type-third conductive via structure coupled to the conductive line CLI.

The active pillar 70 of each pass transistor PT may be disposed to overlap with the corresponding gate contact plug GCT. Accordingly, the interconnection structure (e.g., GCT, V2, CLI, and 85) for a connection between the pass transistor PT and the corresponding conductive layer CDL may be simplified. The respective gate contact plugs GCT may contact corresponding conductive layers CDL, among the plurality of conductive layers CDL, and may then extend towards the second conductive bonding structures 99. The gate contact plugs GCT may be electrically connected to the corresponding active pillars 70 via the second conductive via structures V2, the conductive lines CLI, the second type-third conductive via structures 97, the second conductive bonding structures 99, the first conductive bonding structures 87, and the second type-second conductive connection structures 85.

The semiconductor memory device 50A, illustrated in FIG. 3, may be provided through a process of individually performing a first structure forming process and a second structure forming process and thereafter bonding a first structure to a second structure. The first structure may include the transistor TR, the pass transistor PT, the first conductive connection structures 81, the second conductive connection structures 85, and the first conductive bonding structures 87. The second structure may include the cell array structure CAS, the gate contact plugs GCT, the conductive bit contact plugs BCT, the bit lines BL, the conductive lines CLI, the first conductive via structure V1, the second conductive via structure V2, the third conductive via structure 97, and the second conductive bonding structures 99. The process of bonding the first structure to the second structure may include mutually bonding the first conductive bonding structures 87 to the second conductive bonding structures 99. The doped semiconductor structure DPS, the upper insulating layer UI, and the conductive contact CT may be formed after the first structure is bonded to the second structure.

In an embodiment, as illustrated in FIG. 4, the gate stacked body GST may be interposed between the conductive lines CLI and the pass transistor PT. In this case, the conductive lines CLI and the second type-second conductive connection structures 85 coupled to the pass transistor PT may extend to overlap with the peripheral area (not illustrated) of the semiconductor substrate 61. Via contact plugs (not illustrated) may be disposed between portions of the conductive lines CLI and portions of the second type-second conductive connection structures 85 overlapping with the peripheral area (not illustrated) of the semiconductor substrate 61. The conductive lines CLI may be coupled to the pass transistor PT via the via contact plugs.

Referring to FIG. 4, the second interposed insulating structure IS2 may be disposed between the first interposed insulating structure IS1 and the gate stacked body GST. The doped semiconductor structure DPS may be disposed between the second interposed insulating structure IS2 and the gate stacked body GST so that the doped semiconductor structure DPS is spaced apart from the second conductive connection structures 85.

A method of manufacturing the semiconductor memory device 50B, illustrated in FIG. 4, may include a process of forming a lower structure including the transistor TR, the pass transistor PT, the first conductive connection structures 81, and the second conductive connection structures 85. The process of forming the doped semiconductor structure DPS of the semiconductor memory device 50B, illustrated in FIG. 4, and the process of forming the cell array structure CAS may be performed over the lower structure.

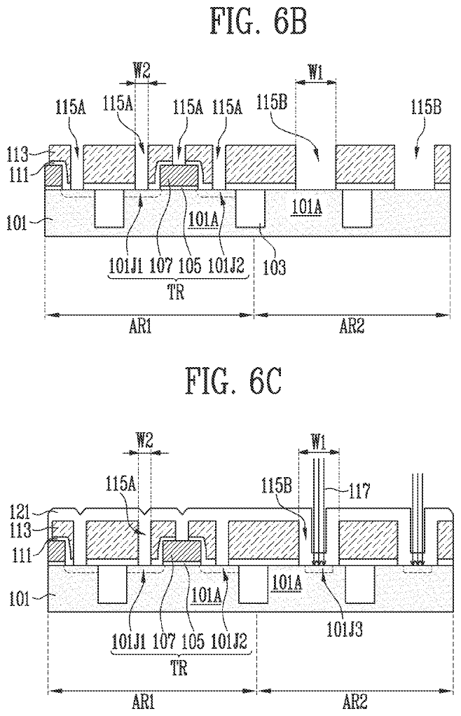

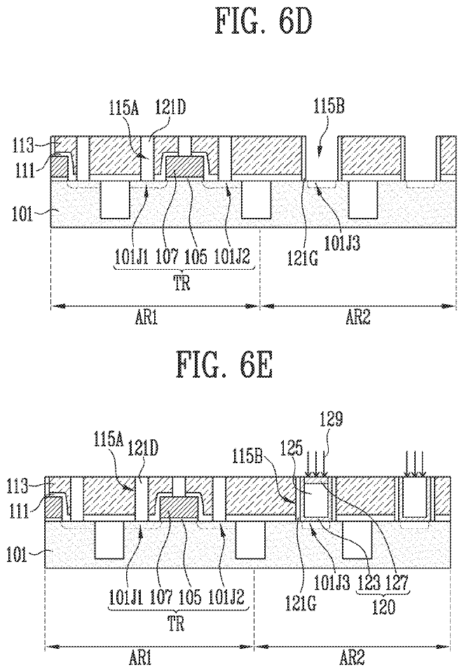

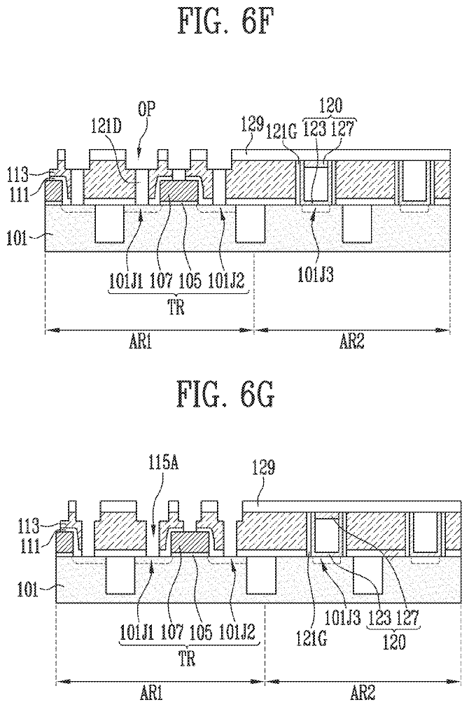

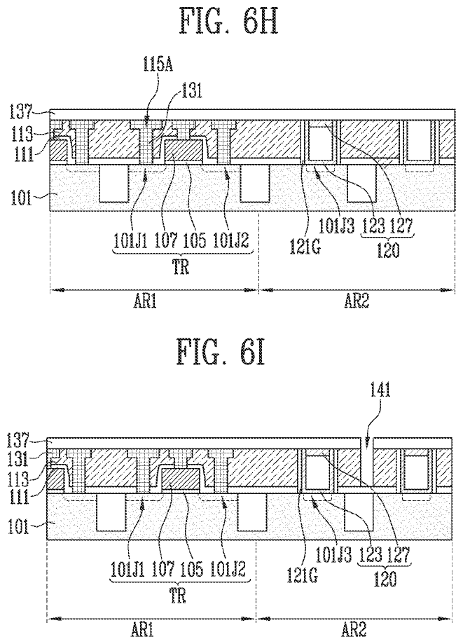

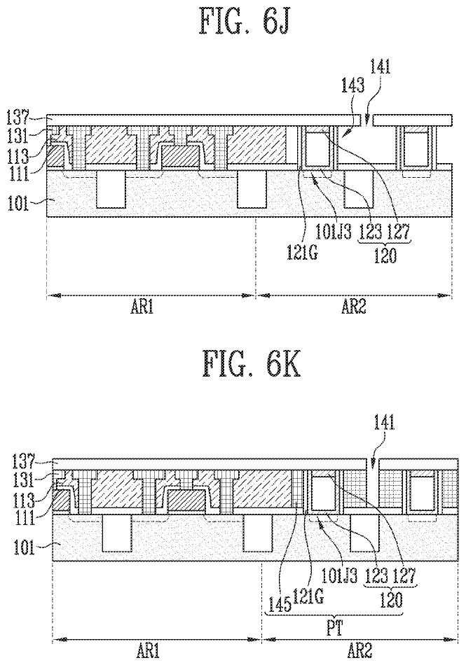

FIGS. 6A to 6K are sectional views illustrating a method of manufacturing first conductive connection structures and a pass transistor group of a semiconductor memory device according to an embodiment of the present disclosure.

Referring to FIG. 6A, a structure including a transistor TR may be formed. In an embodiment, the step of forming the structure may include the step of forming isolation layers 103 that partitions a plurality of active regions 101A in a semiconductor substrate 101, the step of forming a stacked structure of a gate insulating layer 105 and a gate electrode 107 on some of the plurality of active regions 101A, and the step of forming a first junction region 101J1 and a second junction region 101J2 by implanting a conductive impurity into the active regions 101A around the gate electrode 107.

Then, a first insulating layer 111 may be formed over the semiconductor substrate 101 to cover the transistor TR. The first insulating layer 111 may include a first area AR1 overlapping with the transistor TR and a second area AR2 extending sideways from the first area AR1.

Thereafter, a second insulating layer 113 may be formed over the first insulating layer 111. The second insulating layer 113 may include a material having an etch selectivity with respect to the first insulating layer 111. In an embodiment, the first insulating layer 111 may include a silicon oxide layer, and the second insulating layer 113 may include a silicon nitride layer.

The second insulating layer 113 may extend to overlap with the first area AR1 and the second area AR2 of the first insulating layer 111.

Referring to FIG. 6B, a plurality of contact holes 115A and an active hole 115B that pass through the first insulating layer 111 and the second insulating layer 113 may be formed. In an embodiment, a process of forming the plurality of contact holes 115A and the active hole 115B may include the step of forming a mask pattern (not illustrated) over the second insulating layer 113, the step of etching the first insulating layer 111 and the second insulating layer 113 through a plurality of openings in the mask pattern, and the step of removing the mask pattern. The plurality of openings in the mask pattern may correspond to the plurality of contact holes 115A and the active hole 115B, respectively.

The plurality of contact holes 115A may pass through the first area AR1 of the first insulating layer 111 and a portion of the second insulating layer 113 overlapping with the first area AR1. The plurality of contact holes 115A may include a first type-contact hole for exposing the gate electrode 107 of the transistor TR, a second type-contact hole for exposing the first junction region 101J1 of the transistor TR, and a third type-contact hole for exposing the second junction region 101J2 of the transistor TR.

The active hole 115B may pass through the second area AR2 of the first insulating layer 111 and a portion of the second insulating layer 113 overlapping with the second area AR2. The first width W1 of the active hole 115B may be formed to be twice the width of the second width W2 of each contact hole 115A or greater.

Referring to FIG. 6C, a preliminary insulating layer 121 may be formed over the second insulating layer 113. The thickness of the preliminary insulating layer 121 may be controlled such that the preliminary insulating layer 121 fills a central region of each contact hole 115A, but the central region of the active hole 115B is opened. In an embodiment, the thickness of the preliminary insulating layer 121 may be controlled to be half the width of the second width W2 or greater and to be less than half the width of the first width W1.

Then, a conductive impurity 117 may be implanted through the central region of the active hole 115B opened by the preliminary insulating layer 121. In this way, a third junction region 101J3 may be formed in the active region 101A of the semiconductor substrate 101.

Referring to FIG. 6D, a portion of the preliminary insulating layer 121, illustrated in FIG. 6C, may be etched such that the preliminary insulating layer 121 is separated into a pass gate insulating layer 121G and a dummy insulating layer 121D. In this case, a portion of the semiconductor substrate 101 overlapping with the active hole 115B may be exposed, and the second insulating layer 113 may be exposed.

The dummy insulating layer 121D may remain in each of the contact holes 115A, and the pass gate insulating layer 121G may remain on the sidewall of the active hole 115B. The preliminary insulating layer 121, illustrated in FIG. 6C, may be etched through an etching process, such as an etch-back process. The pass gate insulating layer 121G remaining on the sidewall of the active hole 115B may have a reduced thickness compared to the preliminary insulating layer 121 illustrated in FIG. 6C.

Referring to FIG. 6E, in the state in which the dummy insulating layer 121D remains, an active pillar 120 may be formed in the active hole 115B.

The step of forming the active pillar 120 may include the step of forming a channel layer 123 in the active hole 115B. The channel layer 123 may include silicon, germanium, or a mixture thereof. The channel layer 123 may be spaced apart from the second insulating layer 113 by the pass gate insulating layer 121G. The channel layer 123 may extend along the pass gate insulating layer 121G. The channel layer 123 may extend along the surface of a portion of the semiconductor substrate 101 opened by the active hole 115B and may contact the third junction region 101J3.

The channel layer 123 may be formed to open a portion of the central region of the active hole 115B. In this case, the step of forming the active pillar 120 may further include the step of forming a core insulating layer 125 and a semiconductor capping pattern 127 in the portion of the central region of the active hole 11B opened by the channel layer 123. The semiconductor capping pattern 127 may be spaced apart from the third junction region 101J3 due to the core insulating layer 125. The semiconductor capping pattern 127 may include silicon, germanium, or a mixture thereof. The semiconductor capping pattern 127 may be doped with the same conductive impurity 129 as the third junction region 101J3.

In accordance with the above-described series of processes, the active hole 115B for the active pillar 120 may be formed using the process of forming the contact holes 115A, thus reducing the number of unit processes required for manufacturing the semiconductor device.

Referring to FIG. 6F, a buffer layer 129 may be formed over the second insulating layer 113. The buffer layer 129 may include a plurality of openings OP. Each opening OP may expose the corresponding dummy insulating layer 121D. Subsequently, the plurality of contact holes 115A may be opened, as shown in FIG. 6G, by removing the dummy insulating layer 121D exposed through the openings OP.

Referring to FIG. 6G, the gate electrode 107, the first junction region 101J1, and the second junction region 101J2 of the transistor TR may be exposed through the plurality of opened contact holes 115A.

Referring to FIG. 6H, a plurality of first conductive connection structures 131 may be formed in the plurality of contact holes 115A, respectively.

In an embodiment, the step of forming the plurality of first conductive connection structures 131 may include the step of forming a conductive material to fill the plurality of contact holes 115A and the step of separating the conductive material into the plurality of first conductive connection structures 131. In an embodiment, the step of separating the conductive material into the plurality of first conductive connection structures 131 may include the step of removing a portion of the conductive material to expose the second insulating layer 113 through a planarization process such as chemical mechanical polishing (CMP). Here, the buffer layer 129 as illustrated in FIG. 6G may be removed.

The processes of forming the plurality of first conductive connection structures 131 and the active pillar 120 are not limited to the above-described series of processes. In an embodiment, the process of forming the contact holes 115A, illustrated in FIG. 6B, may be performed before the process of forming the active hole 115B, illustrated in FIG. 6B, and the process of forming the active hole 115B, illustrated in FIG. 6B, may be performed after filling the contact holes with the first conductive connection structures 131. The pass gate insulating layer 121G and the active pillar 120 may be formed in the active hole after the first conductive connection structures 131 are formed. In an embodiment, the process of forming the active hole 115B, illustrated in FIG. 6B, may be performed before the process of forming the contact holes 115A, illustrated in FIG. 6B, and the process of forming the contact holes 115A, illustrated in FIG. 6B, may be performed after forming the pass gate insulating layer 121G and the active pillar 120 in the active hole. The first conductive connection structures 131 may be formed in the contact holes after the active pillar 120 is formed.

As described above, after the first conductive connection structures 131 and the active pillar 120 are formed in various manners, a third insulating layer 137 may be formed over the second insulating layer 113, as illustrated in FIG. 6H. The third insulating layer 137 may extend to cover the plurality of first conductive connection structures 131 and the active pillar 120. The third insulating layer 137 may be formed of the same material as the first insulating layer 111. In an embodiment, the third insulating layer 137 may include a silicon oxide layer.

Referring to FIG. 6I, a slit 141 passing through the second insulating layer 113 and the third insulating layer 137 may be formed. The slit 141 may overlap with the second area AR2 of the first insulating layer 111.

Referring to FIG. 6J, a portion of the second insulating layer 113 exposed through the slit 141 may be selectively removed. In this way, the gate region 143 may be opened between the first insulating layer 111 and the third insulating layer 137. The gate region 143 may be defined near the active pillar 120 and the pass gate insulating layer 121G.

Subsequently, the gate region 143 may be filled with a pass gate 145, as illustrated in FIG. 6K.

Referring to FIG. 6K, the pass gate 145 may be formed by injecting a conductive material through the slit 141. The pass gate 145 may be formed to surround the active pillar 120 and the pass gate insulating layer 121G.

The second insulating layer 113 may remain between the first area AR1 of the first insulating layer 111 and the third insulating layer 137 and may face the side portion of the pass gate 145.

The slit 141 may be filled with a conductive material for the pass gate 145 or filled with an insulating material.

Through the above-described series of processes, a pass transistor PT may be formed to include the pass gate 145, the active pillar 120, and the pass gate insulating layer 121G.

Next, a subsequent process of forming the second conductive connection structures, the cell array structure, etc., described above with reference to FIGS. 3 and 4, may be performed.

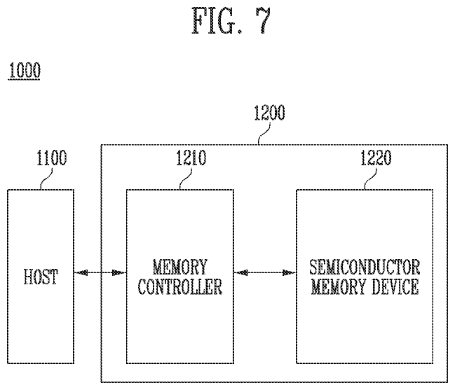

FIG. 7 is a block diagram illustrating an electronic system including a semiconductor memory device according to an embodiment of the present disclosure.

Referring to FIG. 7, an electronic system 1000 may be a computing system, a medical device, a communication device, a wearable device, a memory system, etc. The electronic system 1000 may include a host 1100 and a storage device 1200.

The host 1100 may store data in the storage device 1200 or may read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA (SATA) interface, a parallel-ATA (PATA) interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. In an embodiment, the storage device 1200 may be a storage medium, such as a solid state drive (SSD) or a universal serial bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. As described above with reference to FIG. 3 or 4, the semiconductor memory device 1220 may include a transistor, a cell array structure, a molded insulating structure including a first area disposed between the transistor and the cell array structure and overlapping with the transistor and a second area extending sideways from the first area, a pass gate disposed in the second area of the molded insulating structure, an active pillar penetrating the pass gate, and a pass gate insulating layer disposed between the active pillar and the pass gate.

According to embodiments of the present disclosure, an area occupied by a pass transistor may be reduced, whereby the degree of integration of a semiconductor memory device may be improved.

What is claimed is:

1. A semiconductor memory device, comprising:
a transistor;
a molded insulating structure including a first area overlapping with the transistor and a second area extending sideways from the first area;
a pass gate disposed in the second area of the molded insulating structure;
an active pillar penetrating the pass gate;
a pass gate insulating layer disposed between the active pillar and the pass gate;
a first conductive connection structure disposed in the first area of the molded insulating structure and coupled to the transistor; and
a cell array structure including a plurality of memory cells arranged over the molded insulating structure in three dimensions.

2. The semiconductor memory device according to claim 1, wherein the molded insulating structure comprises:
a first insulating layer covering the transistor and extending along a lower surface of the pass gate;
a second insulating layer disposed over the first insulating layer and adjacent to the pass gate, wherein a side surface of the second insulating layer contacts a side surface of the pass gate; and
a third insulating layer disposed over the second insulating layer and extending along an upper surface of the pass gate.

3. The semiconductor memory device according to claim 2, wherein the second insulating layer includes a material having an etch selectivity with respect to the first insulating layer and the third insulating layer.

4. The semiconductor memory device according to claim 2,
wherein each of the first insulating layer and the third insulating layer includes a silicon oxide layer, and
wherein the second insulating layer includes a silicon nitride layer.

5. The semiconductor memory device according to claim 2, wherein the active pillar penetrates the first insulating layer.

6. The semiconductor memory device according to claim 1, further comprising:
a semiconductor substrate overlapping with the cell array structure with the molded insulating structure interposed therebetween,
wherein the transistor includes a first junction region and a second junction region that are disposed in the semiconductor substrate, and
wherein the first conductive connection structure contacts a corresponding first junction region or a corresponding second junction region to extend towards the cell array structure.

7. The semiconductor memory device according to claim 6, wherein the active pillar comprises:
a channel layer including a horizontal portion contacting the semiconductor substrate, and a tubular vertical portion extending from the horizontal portion towards the cell array structure; and
a semiconductor capping pattern disposed in a central region of the tubular vertical portion of the channel layer.

8. The semiconductor memory device according to claim 7,
wherein the semiconductor substrate includes a third junction region contacting the horizontal portion of the channel layer, and
wherein the third junction region includes the same conductive impurity as the semiconductor capping pattern.

9. The semiconductor memory device according to claim 1, further comprising:
a plurality of slits disposed to be spaced apart from each other in the pass gate.

10. The semiconductor memory device according to claim 1, wherein the cell array structure comprises:
a gate stacked body including a plurality of conductive layers stacked over the molded insulating structure and spaced apart from each other in a first direction;
a channel layer penetrating the gate stacked body; and
a memory layer disposed between the channel layer and the gate stacked body.

11. The semiconductor memory device according to claim 10, further comprising:
a first interposed insulating structure disposed between the gate stacked body and the molded insulating structure;
a second conductive connection structure disposed in the first interposed insulating structure and coupled to the active pillar;
a second interposed insulating structure disposed between the first interposed insulating structure and the gate stacked body;
a first conductive bonding structure disposed in the second interposed insulating structure and coupled to the second conductive connection structure;
a third interposed insulating structure disposed between the second interposed insulating structure and the gate stacked body;
a second conductive bonding structure disposed in the third interposed insulating structure and bonded to the first conductive bonding structure; and
a gate contact plug extending from a conductive layer, corresponding to the second conductive bonding structure among the plurality of conductive layers, towards the second conductive bonding structure.

12. The semiconductor memory device according to claim 10, further comprising:
a first interposed insulating structure disposed between the gate stacked body and the molded insulating structure;
a second conductive connection structure disposed in the first interposed insulating structure and coupled to the active pillar;
a second interposed insulating structure disposed between the first interposed insulating structure and the gate stacked body;
a doped semiconductor structure disposed between the second interposed insulating structure and the gate stacked body and connected to the channel layer; and
a plurality of gate contact plugs coupled to the plurality of conductive layers, respectively, and extending in the first direction.

13. A semiconductor memory device, comprising:
a semiconductor substrate including a first surface facing a first direction and a second surface facing a direction opposite to the first direction;
a gate stacked body including a plurality of conductive layers stacked over the first surface of the semiconductor substrate in the first direction;
a molded insulating structure disposed between the gate stacked body and the semiconductor substrate and including a first area and a second area extending sideways from the first area;
a first conductive connection structure disposed in the first area of the molded insulating structure and extending to contact the semiconductor substrate;
a pass gate disposed in the second area of the molded insulating structure;
an active pillar penetrating the pass gate; and
a pass gate insulating layer disposed between the active pillar and the pass gate.

14. The semiconductor memory device according to claim 13, further comprising:
an interposed insulating structure disposed between the molded insulating structure and the gate stacked body; and
second conductive connection structures disposed in the interposed insulating structure and coupled to the active pillar and the first conductive connection structure, respectively.

15. The semiconductor memory device according to claim 13, wherein the molded insulating structure comprises:
a first insulating layer disposed over the semiconductor substrate and extending along a lower surface of the pass gate;
a second insulating layer disposed over the first insulating layer and adjacent to the pass gate, wherein a side surface of the second insulating layer contacts a side surface of the pass gate; and
a third insulating layer disposed over the second insulating layer and extending along an upper surface of the pass gate.

16. The semiconductor memory device according to claim 15, wherein the second insulating layer includes a material having an etch selectivity with respect to the first insulating layer and the third insulating layer.

17. The semiconductor memory device according to claim 15, wherein the first insulating layer is penetrated by the first conductive connection structure and the active pillar.

18. The semiconductor memory device according to claim 13, further comprising:
a plurality of slits disposed to be spaced apart from each other in the pass gate.

19. The semiconductor memory device according to claim 13, further comprising:
a channel layer penetrating the gate stacked body;
a memory layer disposed between the channel layer and the gate stacked body;
a gate contact plug disposed between the gate stacked body and the molded insulating structure and coupled to a corresponding conductive layer among the plurality of conductive layers;
a first conductive bonding structure coupled to a second conductive connection structure corresponding to the gate contact plug among the second conductive connection structures; and
a second conductive bonding structure coupled to the gate contact plug and bonded to the first conductive bonding structure.

20. The semiconductor memory device according to claim 13, further comprising:
a channel layer penetrating the gate stacked body;
a memory layer disposed between the channel layer and the gate stacked body;
a doped semiconductor structure disposed between the gate stacked body and the molded insulating structure and coupled to the channel layer; and
a plurality of gate contact plugs coupled to the plurality of conductive layers, respectively, and extending in the first direction.
